(19) United States
(12) Patent Application Publication
(10) Pub. No.: US 2007/0069320 A1
(43) Pub. Date: Mar. 29, 2007

(54) Wiring structure of a semiconductor package and method of manufacturing the same, and wafer level package having the wiring structure and method of manufacturing the same

(75) Inventors: In-Young Lee, Yongin-si (KR); Sung-Min Sim, Seongnam-si (KR); Dong-Hyeon Jang, Suwon-si (KR); Hyun-Soo Chung, Hwaseong-si (KR); Jae-Sik Chung, Yongin-si (KR); Seung-Kwan Ryu, Yongin-si (KR); Myeong-Soon Park, Suwon-si (KR); Jong-Kook Yoon, Anseong-si (KR); Ju-Il Choi, Cheongju-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/486,041

(22) Filed: Jul. 14, 2006

(30) Foreign Application Priority Data
Aug. 19, 2005 (KR) 2005-76286

(51) Int. Cl. H01L 31/00

(52) U.S. Cl. 257/459

(57) ABSTRACT

A wiring structure may include a pad, a conductive pattern and an insulating photoresist structure. The pad may be provided on a body and electrically connected to a circuit unit of the body. The conductive pattern may be provided on the body and may be electrically connected to the pad. The insulating photoresist structure may be provided on a surface of the conductive pattern. The insulating photoresist structure may have a contact hole through which the conductive pattern may be partially exposed. The insulating photoresist structure may be fabricated by providing a photosensitive photoresist film on the conductive layer, and patterning the photosensitive photoresist film by two photo processes.

### PRIORITY STATEMENT

This application claims priority under 35 USC § 119 from Korean Patent Application No. 2005-76286, filed on Aug. 19, 2005, the contents of which are herein incorporated by reference in its entirety.

### BACKGROUND

1. Field of the Invention

Example embodiments of the present invention relate to a wiring structure of a semiconductor package and a method of manufacturing the wiring structure, and a wafer level package having the wiring structure and a method of manufacturing the wafer level package. More particularly, example embodiments of the present invention relate to a wiring structure that may be manufactured by simpler processes; a method of manufacturing the wiring structure, a wafer level package having the wiring structure and a method of manufacturing the wafer level package.

2. Description of the Related Art

A semiconductor device, which may be formed on a silicon substrate, may be susceptible to damage by an impact that may be applied from an exterior, moisture, and/or oxygen, for example. Thus, semiconductor devices may be packaged for protection.

A chip scale package such as a ball grid array (BGA) package and a wafer level package have been developed. The chip scale package may have a volume substantially similar to that of the semiconductor device based on a volume of the semiconductor device.

The chip scale package may include a conductive pattern and a conductive bump. The conductive pattern may make electrical contact with a pad of the semiconductor device, which may provide access for external electrical connections to the semiconductor device. The conductive bump may be electrically connected to a land pattern that may be formed at an edge of the conductive pattern. The conductive bumps of the chip scale package may be arranged on the semiconductor chip in a matrix configuration.

Methods of manufacturing a chip scale package are well known in this art.

According to a conventional method of manufacturing the chip scale package, a first photoresist pattern may be formed on a conductive layer. The conductive layer may be patterned using the first photoresist pattern as an etching mask to form a conductive layer pattern. An insulation layer may be formed on the conductive layer pattern. A second photoresist pattern may be formed on the insulation layer. The insulation layer may be etched using the second photoresist pattern as an etching mask to form an insulation layer pattern partially exposing the conductive layer pattern. The conductive bump may be attached to the exposed conductive layer pattern.

Thus, according to conventional wisdom, the method of manufacturing the chip scale package may involve forming the first photoresist pattern and forming the second photoresist pattern. As a result, the conventional method may be complicated and time consuming.

### SUMMARY

According to an example, non-limiting embodiment, a wiring structure may include a body having a circuit unit. A pad may be provided on the body and may be electrically connected to the circuit unit. A conductive pattern may be provided on the body and may be electrically connected to the pad. An insulating photoresist structure may be provided on a surface of the conductive pattern. The insulating photoresist structure may have a contact hole through which the conductive pattern may be partially exposed.

According to another example, non-limiting embodiment, method of manufacturing a wiring structure may involve providing a first insulation pattern on a body that may include a circuit unit and a pad that may be electrically connected to the circuit unit. The pad may be exposed through the first insulation pattern. A conductive layer may be provided on the first insulation pattern. The conductive layer may be electrically coupled to the pad. An insulating photoresist film may be provided on the conductive layer. The insulating photoresist film may be exposed and developed to provide a preliminary photoresist structure on the conductive layer. The conductive layer may be etched using the preliminary photoresist structure as an etching mask to provide a conductive pattern on the body. The preliminary photoresist structure may be exposed and developed to provide an insulating photoresist structure having a contact hole through which the conductive pattern may be exposed.

### BRIEF DESCRIPTION OF THE DRAWINGS

Example, non-limiting embodiments of the present invention will be described with reference to the accompanying drawings.

FIG. 1 is a plan view of a wiring structure of a semiconductor package in accordance with an example, non-limiting embodiment of the present invention.

FIG. 2 is a cross-sectional view taken along the line 2-2 in FIG. 1.

FIG. 3 is a cross-sectional view taken along the line 3-3 in FIG. 1.

FIGS. 4 to 7 are cross-sectional views of a method that may be implemented to manufacture the wiring structure of the semiconductor package in FIGS. 1 to 3.

FIG. 8 is a cross-sectional view of a wiring structure of a semiconductor package in accordance with another example, non-limiting embodiment of the present invention.

FIGS. 9 and 10 are cross-sectional views of a method the may be implemented to manufacture the wiring structure of the semiconductor package in FIG. 8.

FIG. 11 is a plan view of a wafer having wafer level packages in accordance with another example, non-limiting embodiment of the present invention.

FIG. 12 is a rear view of the wafer level package in FIG. 1 1.

FIG. 13 is a cross-sectional view taken along the line 13-13 in FIG. 12.

FIGS. 14 to 18 are plan views and cross-sectional views of a method that may be implemented to manufacture the wafer level package in FIG. 13.

FIG. 19 is a cross-sectional view of an under bump layer of a wafer level package in accordance with another example, non-limiting embodiment of the present invention.

FIG. 20 is an enlarged cross-sectional view showing a portion 20 in FIG. 19.

FIGS. 21 and 22 are cross-sectional views of a method the may be implemented to form the under bump layer of the wafer level package in FIG. 19.

FIG. 23 is a cross-sectional view of a wafer level package in accordance with another example, non-limiting embodiment of the present invention.

FIGS. 24 to 26 are cross-sectional views of a method that may be implemented to manufacture the wafer level package in FIG. 23.

### DESCRIPTION OF EXAMPLE, NON-LIMITING EMBODIMENTS

Example, non-limiting embodiments of the invention are described with reference to the accompanying drawings. The invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity. The drawings are not to scale. Like reference numerals refer to like elements throughout.

It will be understood that when an element or layer is referred to as being “on,” “connected to” and/or “coupled to” another element or layer, it can be directly on, connected and/or coupled to the other element or layer or intervening elements or layers may be present. In contrast, when an element is referred to as being “directly on,” “directly connected to” and/or “directly coupled to” another element or layer, there are no intervening elements or layers present. As used herein, the term “and/or” includes any and all combinations of one or more of the associated listed items.

Although the terms first, second, etc. may be used to describe various elements, components, regions, layers and/or sections, these elements, components, regions, layers and/or sections should not be limited by these terms. These terms may be used to distinguish one element, component, region, layer or section from another region, layer or section. For exanple, a first element, component, region, layer and/or section discussed below could be termed a second element, component, region, layer and/or section without departing from the teachings of the present invention.

Spatially relative terms, such as “beneath,” “below,” “lower,” “above,” “upper” and the like, may be used herein for ease of description to describe one element and/or feature's relationship to another element(s) and/or feature(s), for example, as illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements and/or features. The device may be otherwise oriented (rotated 90 degrees or at other orientations) and the spatially relative descriptors used herein interpreted accordingly.

The terminology used herein is for the purpose of describing example embodiments only and is not intended to be limiting of the invention. As used herein, the singular terms “a,” “an” and “the” are intended to include the plural forms as well, unless the context clearly indicates otherwise. it will be understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The following description refers to cross-section illustrations, which may be schematic illustrations of example embodiments (and intermediate structures). As such, variations from the shapes of the illustrations as a result, for example, of manufacturing techniques and/or tolerances, may be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded and/or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures may be schematic in nature and their shapes are not intended to illustrate the actual shape of a region of a device and are not intended to limit the scope of the invention.

Unless otherwise defined, all terms (including technical and scientific terms) used herein may have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized and/or overly formal sense unless expressly so defined herein.

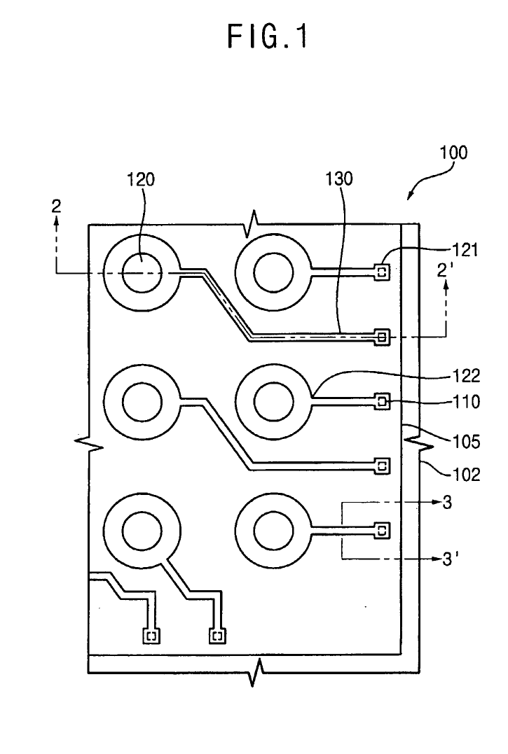

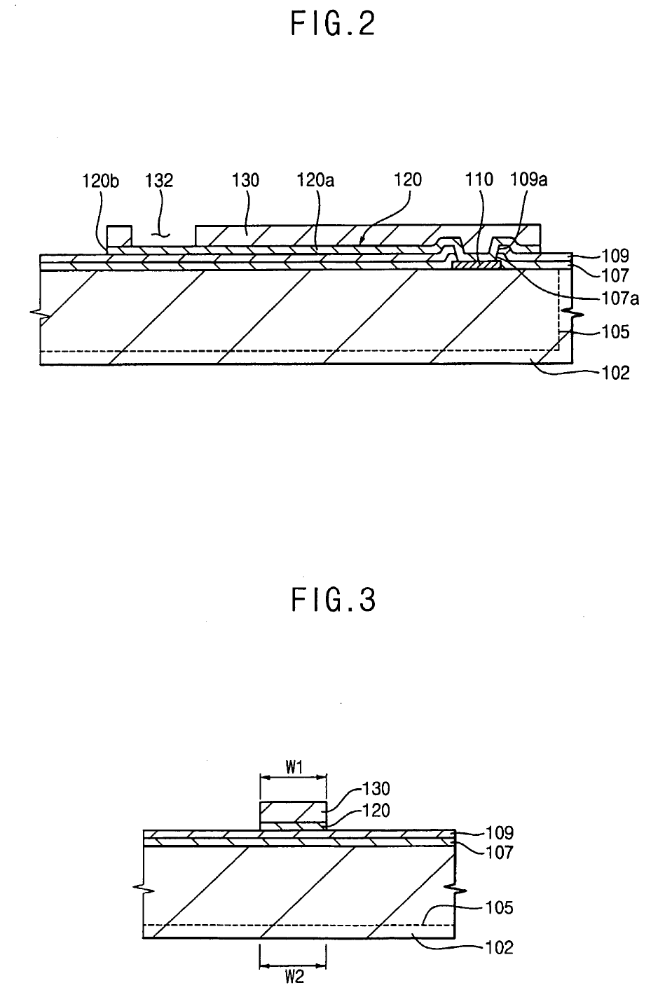

FIG. 1 is a plan view of a wiring structure 100 of a semiconductor package in accordance with an example, non-limiting embodiment of the present invention. FIG. 2 is a cross-sectional view taken along the line 2-2 in FIG. 1. FIG. 3 is a cross-sectional view taken along the line 3-3 in FIG. 1.

Referring to FIGS. 1 to 3, the wiring structure 100 of a semiconductor package may include a pad 110, a conductive pattern 120 and an insulating photoresist structure 130.

The pad 110 may be placed on a body 102 having a circuit unit 105. In this example embodiment, the body 102 may include a flexible polyimide substrate that may be used for a ball grid array (BGA) package or a silicon wafer. The pad 110 may provide access for external electrical connections to the circuit unit 105. For example, the pad 110 may input an input signal applied from an exterior of the package into the circuit unit 105 and/or output a data signal processed in the circuit unit 105 to the exterior. At least two pads 110 may be provided on the body 120 to transmit the input signal and the data signal to a plurality of devices.

The pad 110 may be fabricated from aluminum, aluminum alloy, gold, silver, and/or copper, for example. These materials may be used alone or in combination.

The conductive pattern 120, which may be electrically connected to the pad 1I O, may be provided on the body 102. As shown in FIGS. 1 and 2, the conductive pattern 120 may include a conductive body 120a and a land portion 120b, which may be integrally formed with the conductive body 120a (for example).

The conductive body 120a may have an elongated shape. The conductive body 120a may include a first end 121 that may be electrically connected to the pad 110 and a second end 122 that may be opposite to the first end 121. The conductive bodies 120a may be electrically connected to each of the pads 110 and may have lengths different from each other in accordance with positions of the pads 110 and an arrangement of a conductive bump, which will be discussed and illustrated later. In this example embodiment, the conductive pattern 120 may have a thickness of about 1,000 Å to about 7,000 Å.

The land portion 120b may be electrically connected to the second end 122 of the conductive body 120a. The land portion 120b may have a disc shape, for example. In alternative embodiments, the land portion 120b may have any geometrical shape.

In this example embodiment, the conductive pattern 120 may include Ti/Cu, TiW/Ni, Ti/Ni, TiW/NiV, Cr/Cu, Cr/Ni, Cr/NiV, Ti/Cu/Ni, Tiw/Cu/Ni, TiW/Cu/NiV, and/or Cr/Cu/NiV, for example. These materials may be used alone or in combination.

Referring to FIG. 2, a passivation pattern 107 may be provided on the body 102. The passivation pattern 107 may be interposed between the body 102 and the conductive pattern 120. The passivation pattern 107 may absorb an impact applied from an exterior to protect the circuit unit 105 from damage. In this example embodiment, the passivation pattern 107 may be fabricated from an oxide layer and/or a nitride layer, for example.

An opening 107s may be provided through the passivation pattern 107. The pad 110 may be exposed through the opening 107a.

A first insulation pattern 109 may be provided on the body 102. The first insulation pattern 109 may be interposed between the passivation pattern 107 and the conductive pattern 120. The first insulation pattern 109 may have a thickness of about 1 μm to about 25 μm, for example.

The first insulation pattern 109 may absorb impacts and/or stresses that may be applied to the exterior of the body 102 to protect the circuit unit 105 from damage. The first insulation pattern 109 may insulate the circuit unit 105 from an external conductive body (not shown). The first insulation pattern 109 may be fabricated from a photosensitive polyimide film, for example.

The first insulation pattern 109 may have an opening 109a that may correspond to the opening 107a. The pad 110 may be exposed through the openings 107a and 109a. Thus, the conductive pattern 120 may be electrically connected to the pad 110 through the openings 107a and 109a.

Referring to FIGS. 2 and 3, the insulating photoresist structure 130 may be placed on an upper face of the conductive pattern 120. By way of example only, an outline of the insulating photoresist structure 130 may be substantially similar to that of the conductive pattern 120. Thus, the insulating photoresist structure 130 may have a first width W1 substantially the same as a second width W2 of the conductive pattern 120. The insulating photoresist structure 130 may have a contact hole 132 for partially exposing the land portion 120b of the conductive pattern 120. The insulating photoresist structure 130 may have a thickness of about 1 μm to about 25 μm, for example.

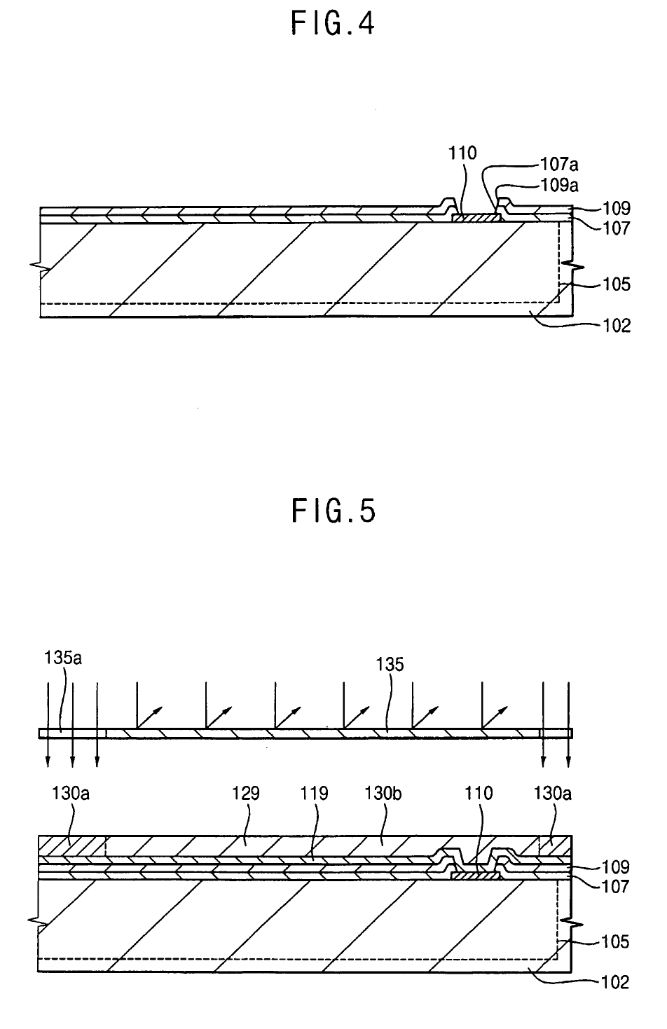

A method that may be implemented to manufacture the wiring structure 100 of the semiconductor package will be discussed with reference to FIGS. 4-7.

FIG. 4 is a cross-sectional view of forming the passivation pattern 107 and the first insulation pattern 109.

Referring to FIG. 4, the circuit unit 105 may be formed in the body 102. The circuit unit 105 may be formed by various semiconductor manufacturing processes that are well known in this art. In this example embodiment, the body 102 may include a flexible polyimide substrate used for a BGA package or a silicon wafer, for example.

The pad 110 may be provided on the body 102 and may be electrically connected to the circuit unit 105.

To form the pad 110, a pad metal layer (not shown) may be provided on the body 102. The pad metal layer may be provided by a sputtering process and/or a chemical vapor deposition process, for example. The pad metal layer may be an aluminum layer and/or an aluminum alloy layer, for example. These materials can be used alone or in combination.

A photoresist film (not shown) may be provided on the pad metal layer. The photoresist film may be provided by a spin coating process, for example. The photoresist film may be patterned by a photo process including an exposing process and a developing process to provide a photoresist pattern (not shown) on an upper face of the pad metal layer. The photoresist pattern may cover a portion of the pad metal layer where the pad 110 is to be formed. In this example embodiment, the photoresist pattern may be provided on a position of pad metal layer corresponding to an input terminal and/or an output terminal of the circuit unit 105.

The pad metal layer may be etched using the photoresist pattern as an etching mask, thereby forming the pad 110 on the body 102 that is electrically connected to the input terminal and/or the output terminal of the circuit unit 105. The photoresist pattern remaining on the pad 110 may be removed by an ashing process and/or stripping process, for example.

A passivation layer (not shown) and a first insulation layer (not shown) may be sequentially provided on the body 102.

The passivation layer may be provided on the body 102 by a chemical vapor deposition (CVD) process and/or a high-density plasma (HDP) deposition process, for example. In this example embodiment, the passivation layer may be an oxide layer and/or a nitride layer, for example.

The first insulation layer may be provided on an upper face of the passivation layer. The first insulation layer may have a thickness of about 1 μm to about 25 μm, for example. The first insulation layer may be fabricated from a photosensitive polyimide film, for example.

The first insulation layer may be patterned by a photolithography process including an exposing process and a developing process to form the first insulation pattern 109 having the first opening 109a, which corresponds to the pad 110. The first insulation pattern 109 may absorb impacts that may be applied from an exterior to protect the body 102 and the circuit unit 105. Additionally, the first insulation pattern 109 may insulate the circuit unit 105 from an external conductive body.

In this example embodiment, the first insulation layer may be exposed by a light beam having exposure energy of about 500 mJ to about 2,500 mJ, for example.

According to another example embodiment, the first insulation layer may include an oxide layer and/or a nitride layer (for example) instead of the photosensitive polyimide film. Here, a photoresist pattern may be provided on the first insulation layer. The first insulation layer may be etched using the photoresist pattern as an etching mask to form the first insulation pattern 109 having the opening 109a.

The passivation layer may be etched using the first insulation pattern 109 as an etching mask to form the passivation pattern 107 on the body 102. The passivation pattern 107 may have the opening 107a corresponding to the opening 109a. Thus, the pad 110 may be exposed through the openings 109a and 107a.

FIG. 5 is a cross-sectional view of providing a conductive layer 119 and an insulating photoresist film 129 on the first insulation pattern 109 in FIG. 4.

Referring to FIG. 5, the conductive layer 119 may be provided on an entire surface of the body 102 to cover the first insulation pattern 109. Thus, the conductive layer 119 may be provided along a profile of the openings 109a and 107a. The conductive layer 119 may be provided by a sputtering process and/or a CVD process, for example. In this example embodiment, the conductive layer 119 may include Ti/Cu, TiW/Ni, Ti/Ni, TiW/NiV, Cr/Cu, Cr/Ni, Cr/NiV, Ti/Cu/Ni, TiW/Cu/Ni, TiW/Cu/NiV and/or Cr/Cu/NiV, for example. These materials may be used alone or in combination. The conductive layer 119 may have a thickness of about 1,000 Å to about 7,000 Å. The conductive layer 119 may have a concave portion due to the profile of the openings 109a and 107a.

The insulating photoresist film 129 may be provided on the conductive layer 119 to fill up the concave portion. The insulating photoresist film 129 may be provided by a spin coating process, for example. In this example embodiment, the insulation photoresist film 129 may be fabricated from a photosensitive polyimide film, for example. For example, the insulating photoresist film 129 may be a positive photosensitive insulating photoresist film.

A first reticle 135 having a light-transmitting portion 135a may be aligned over the insulating photoresist film 129.

The insulating photoresist film 129 may be exposed by a light beam passing through the light-transmitting portion 135a of the first reticle 135 to form an exposed region 130a and a non-exposed region 130b of the insulating photoresist film 129. The exposed region 130a may correspond to the light-transmitting portion 135a of the first reticle 135. The non-exposed region 130b may exist around the exposed region 130a. A solubility of the exposed region 130a with respect to a developing solution is higher than that of the non-exposed region 130b because a photoresist substance in the exposed region 130a may react with the light beam. Here, exposure energy for the exposed region 130a of the insulating photoresist film 129 may be about 500 mJ to about 2,500 mJ, for example.

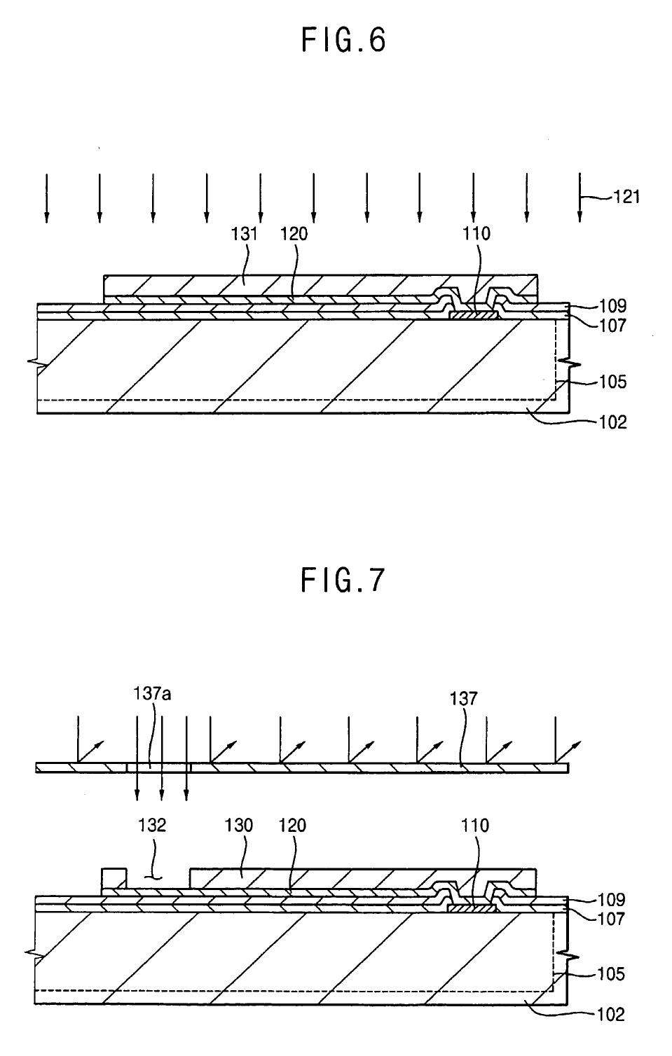

FIG. 6 is a cross-sectional view of forming a preliminary photoresist structure 131 and a conductive pattern 120.

Referring to FIG. 6, the insulating photoresist film 129 is developed using the developing solution, thereby removing the exposed region 130a of the insulating photoresist film 129 to form a preliminary photoresist structure 131 on the conductive layer 119. By way of example only, the preliminary photoresist structure 131 may include a disc portion and an elongated portion extending from the disc portion, as shown in FIG. 1. In this example embodiment, a portion of the preliminary photoresist structure 131 may cover the pad 110.

The conductive layer 119 may be etched using the preliminary photoresist structure 131 as an etching mask to form a conductive pattern 120 that may be electrically connected to the pad 110. By way of example only, the conductive layer 119 may be wet etched using an etchant 121 having a high etching selectivity relative to the first insulation pattern 109.

FIG. 7 is a cross-sectional view of providing an insulating photoresist structure 130 by patterning the preliminary photoresist structure 131 in FIG. 6.

Referring to FIG. 7, a second reticle 137 may be placed over the preliminary photoresist structure 131, which may still have a photosensitivity. The second reticle 137 may have a light-transmitting portion 137a partially overlapped with the conductive pattern 120. A light beam passing through the light-transmitting portion 137a of the second reticle 137 may secondarily expose a portion of the preliminary photoresist structure 131. In this example embodiment, the exposed portion of the preliminary photoresist structure 131 may correspond to the light-transmitting portion 137a. Here, second exposure energy for exposing the portion of the preliminary photoresist structure 131 may be about 500 mJ to about 2,500 mJ, for example. The secondarily exposed preliminary photoresist structure 131 may be developed using a developing solution so that a secondarily exposed portion of the preliminary photoresist structure 131 may be removed from the preliminary photoresist structure 131. Thus, the insulating photoresist structure 130 may have a contact hole 132 that partially exposes a portion of the conductive pattern 120. The insulating photoresist structure 130 having the contact hole 132 may be hardened by a bake process.

According to this example embodiment, the insulating photoresist film 129 may be exposed and developed to provide the preliminary photoresist structure 131 on the conductive pattern 120, and the preliminary photoresist structure 131 may be exposed and developed to form the insulating photoresist structure 130. Thus, the insulating photoresist structure 130 may be manufactured by two photo processes and without an ashing process and/or a stripping process for removing a photoresist pattern.

In this example embodiment, the insulating photoresist structure 130 may include the positive photosensitive insulating photoresist substance. Alternatively, the insulating photoresist structure 130 may include a negative photosensitive insulating photoresist substance. When the insulating photoresist structure 130 may include the negative photosensitive insulating photoresist substance, it will be appreciated that a reticle having a pattern that is reverse to those of the reticles 135 and 137 in FIGS. 5 and 7 may be suitably implemented.

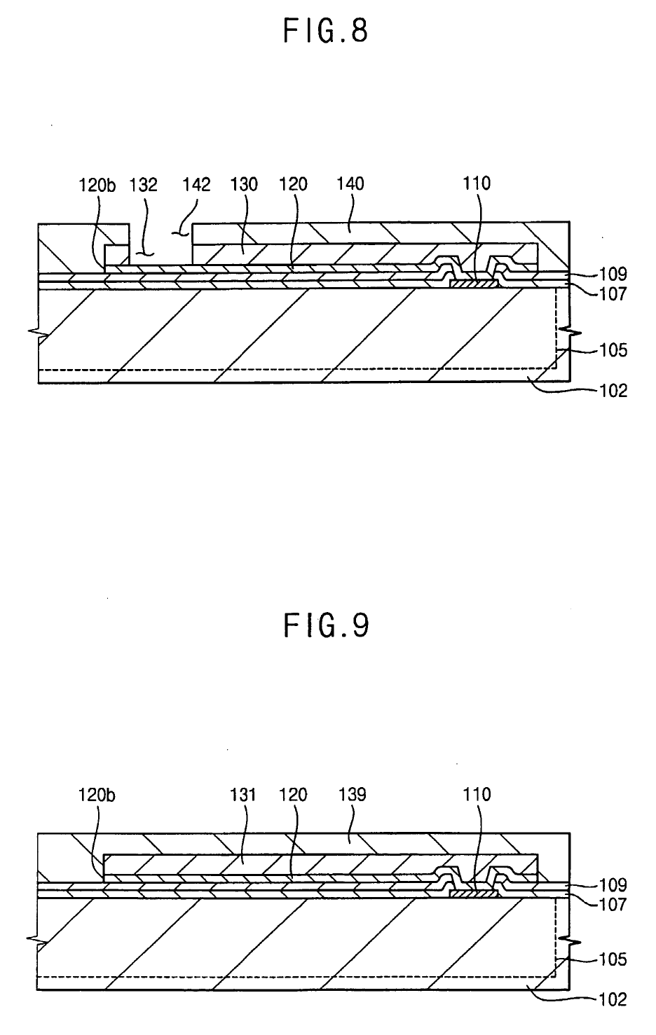

FIG. 8 is a cross-sectional view of a wiring structure of a semiconductor package in accordance with another example, non-limiting embodiment of the present invention. The wiring structure of this example embodiment may include elements substantially similar to those in the wiring structure of previous example embodiment, except that a second insulation pattern 140 may be provided. Thus, the same reference numerals refer to substantially similar elements in FIGS. 1 to 3 and any further illustrations of the similar elements is omitted.

Referring to FIG. 8, the second insulation pattern 140 may be provided on the first insulation pattern 109 of the wiring structure. The second insulation pattern 140 may cover the insulating photoresist structure 130. In this example embodiment, the second insulation pattern 140 may have a thickness of about 1 μm to about 30 μm, for example. The second insulation pattern 140 may be fabricated from a photosensitive polyimide film, for example.

An opening 142 may be provided through a portion of the second insulation pattern 140. The opening 142 may correspond to the contact hole 132 of the insulating photoresist structure 130. The conductive pattern 120 may be partially exposed through the opening 142. The second insulation pattern 140 may insulate sidewalls of the conductive pattern 120 from an external conductive body (not shown). Further, the second insulation pattern 140 may absorb impacts applied from an exterior to protect the conductive pattern 120 and the circuit unit 105 from damage.

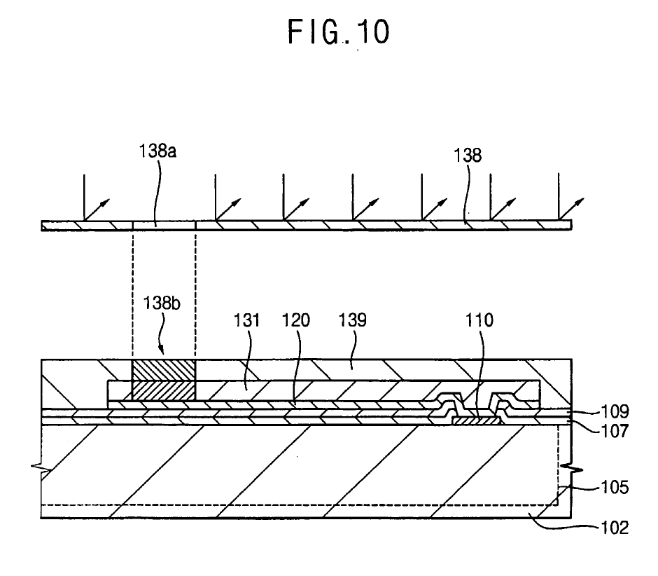

A method that may be implemented to manufacture the wiring structure of FIG. 8will be described with reference to FIGS. 9 and 10. The method may be substantially similar to that shown in FIGS. 4-7, except for providing the second insulation pattern 140. Thus, the same reference numerals in FIGS. 9 and 10 refer to substantially similar elements in FIGS. 4 to 7 so that any further illustrations of the same elements are omitted.

Processes may be carried out in substantially the same manner as those illustrated with reference to FIGS. 4 to 6 to form the preliminary photoresist structure 131 and the conductive pattern 120 on the body 102.

Referring to FIG. 9, a second insulation layer 139 may be provided on an entire surface of the body 102 to cover the preliminary photoresist structure 131. In this example embodiment, the second insulation layer 139 may be provided by a spin coating process, for example. The second insulation layer 139 may be fabricated from a photosensitive polyimide film, for example, which may be substantially the same as that used for the preliminary photoresist structure 131.

FIG. 10 is a cross-sectional view of exposing the second insulation layer 139.

Referring to FIG. 10, a second reticle 138, which may have a light transmitting portion 138a, may be arranged over the second insulation layer 139. In this example embodiment, the light transmitting portion 138a may be partially overlapped by the second insulation layer 139 so that the light-transmitting portion 138a may be positioned over a portion of the second insulation layer 139 where a contact hole partially exposing the conductive pattern 120 is to be formed. In this example embodiment, the second reticle 138 may be substantially the same as the second reticle 137 in FIG. 7.

A light beam may pass through the second reticle 138 and be irradiated onto the second insulation layer 139 and the preliminary photoresist structure 131. In this way, the second insulation layer 139 and the preliminary photoresist structure 131 may be exposed by the light beam. As a result, optical reactions are generated by exposed portions 138b of the second insulation layer 139 and the preliminary photoresist structure 131 so that the exposed portions 138b have a solubility higher than that of non-exposed portions of the second insulation layer 139 and the preliminary photoresist structure 131. In this example embodiment, exposure energy for the exposed portions 138b of the second insulation layer 139 and the preliminary photoresist structure 131 may be about 500 mJ to about 3,000 mJ, for example.

Hence, the exposed regions 138b of the second insulation layer 139 and the preliminary photoresist structure 131 may be developed by a developing process to remove the photosensitive substance from the exposed region 138b. Thus, the insulating photoresist structure 130 having a contact hole 132 and the second insulation pattern 140 having a contact hole 142 may be provided on the body 102. The conductive pattern 120 may be partially exposed through the contact holes 132 and 142.

In this example embodiment, the insulating photoresist structure 130 may include the positive photosensitive insulating photoresist substance. Alternatively, the insulating photoresist structure 130 may include a negative photosensitive insulating photoresist substance instead of the positive photosensitive insulating photoresist substance.

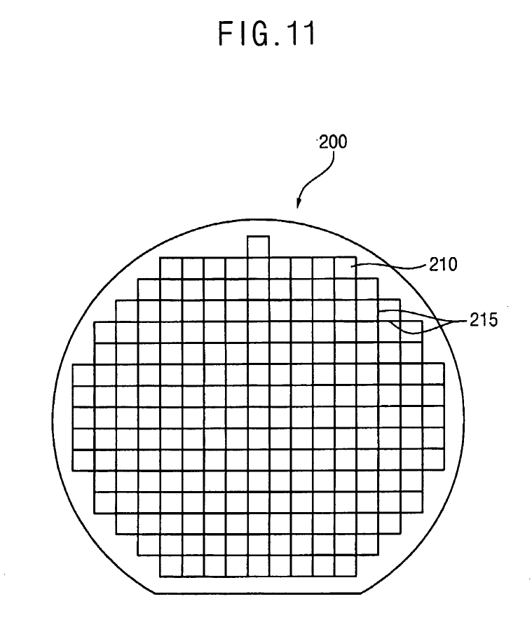

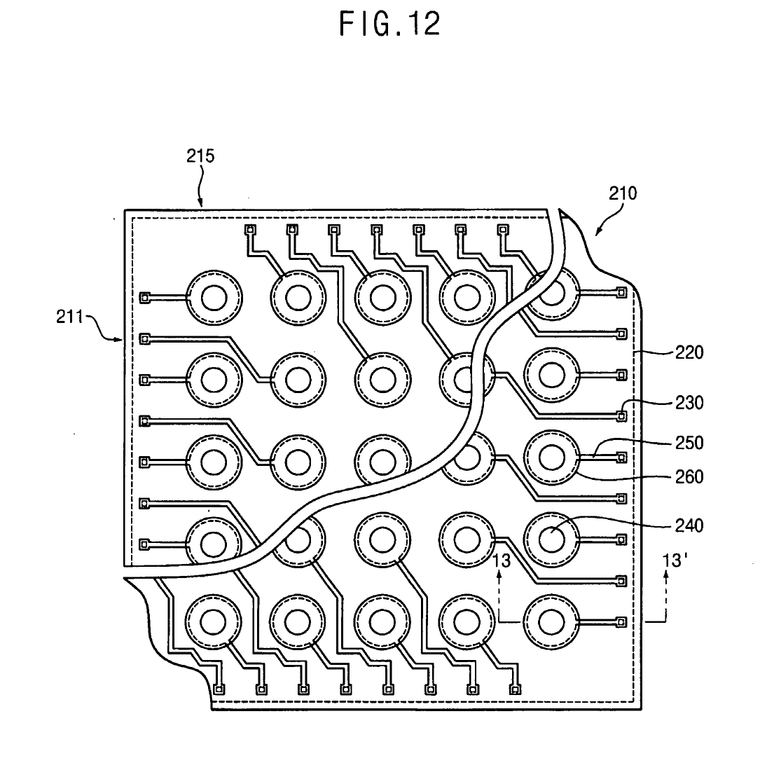

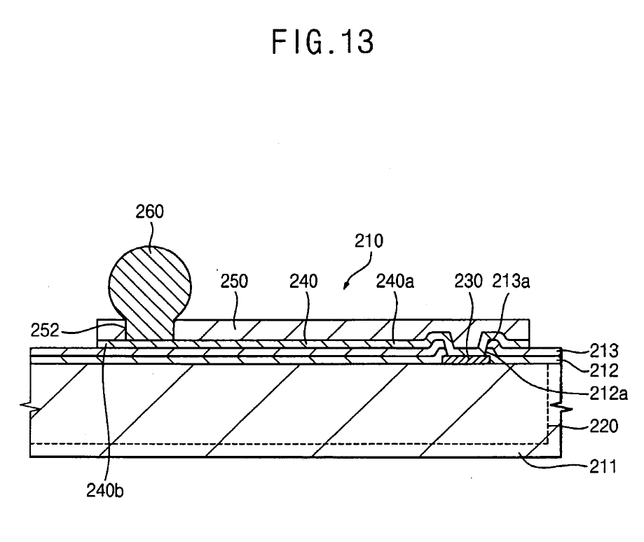

FIG. 11 is a plan view of a wafer 200 having wafer level packages 210 in accordance with another example, non-limiting embodiment of the present invention. FIG. 12 is a rear plan view of the wafer level package 210 in FIG. 11. FIG. 13 is a cross-sectional view taken along the line 13-13 in FIG. 12.

Referring to FIG. 11, the wafer 200 may include a plurality of wafer level packages 210 and scribe lanes 215 for singulating the wafer level packages from the wafer 200. The scribe lines 215 may be provided between the wafer level packages 210.

Referring to FIGS. 12 and 13, the wafer level package 210 may include a semiconductor chip 211 having a circuit unit 220, a pad 230, a conductive pattern 240, an insulating photoresist structure 250, and a conductive bump 260.

The circuit unit 220 of the semiconductor chip 211 may (for example) process an input signal applied from an exterior to generate a data signal. In this example embodiment, the semiconductor chip 211 may have a square shape or rectangular shape.

The pad 230 may be electrically connected to the circuit unit 220 to input the input signal into the circuit unit 220 and/or to output the data signal processed in the circuit unit 220 to the exterior.

A plurality of the pads 230 may be arranged along an edge of the semiconductor chip 211 in a line. Alternatively, a plurality of the pads 230 may be arranged along the edge of the semiconductor chip in a plurality of lines. When the pads 230 are arranged along the edge of the semiconductor chip 211 in a plurality of lines, the pads 230 may be arranged in a zigzag shape, for example.

The pad 230 may be fabricated from a conductive material such as a metal, for example. The pad 230 may have a square plate shape or a circular plate shape. In alternative embodiments, the pad may have any other geometric shape. The pad 230 may be fabricated from an aluminum layer, an aluminum alloy layer, a gold layer, a silver layer, and/or a copper layer, for example. These materials may be used alone or in combination. In this example embodiment, the pad 230 may includes the aluminum layer and/or the aluminum alloy layer.

Referring to FIG. 13, a passivation pattern 212 and a first insulation pattern 213 may be provided on the semiconductor chip 211 having the pad 230.

The passivation pattern 212 may be provided on an upper face of the semiconductor chip 211. The passivation pattern 212 may be fabricated from a nitride layer and/or an oxide layer, for example. An opening 212a, which may expose the pad 230, may be provided through the passivation pattern 212. The passivation pattern 212 may absorb impacts that may be applied to an exterior to protect the circuit unit 220 formed in the semiconductor chip 211 from damage.

The first insulation pattern 213 may be provided on the passivation pattern 212. The first insulation pattern 213 may be fabricated from a photosensitive polyimide film, for example. The first insulation pattern 213 may have an opening 213a that may expose the pad 230. The opening 213a provided through the first insulation pattern 213 may correspond to the opening 212a provided through the passivation pattern 212 to partially expose the pad 230. The first insulation pattern 213 may absorb impacts that may be applied to the exterior to protect the circuit unit 220 from damage, and may also insulate the circuit unit 220 from an external conductive body (not shown).

The conductive pattern 240 may be provided on the first insulation pattern 213. The conductive pattern 240 may include a conductive body 240a and a land portion 240b.

The conductive body 240a may be electrically connected to the pad 230. The conductive body 240 may have an elongated shape. The conductive body 240a may include a first end and a second end opposite to the first end. As shown in FIG. 12, each of the conductive bodies 240a may have lengths different from each other in accordance with positions of the pads 230 and an arrangement of the conductive bump 260.

One end of the conductive body 240a may be electrically connected to the pad 230. The other end of the conductive body 240a may be electrically connected to the land portion 240b. The land portion 240b may have a disc shape on a plan view. In alternative embodiments, the land portion 240b may have any other geometric shape. The land portions 240 may be arranged on a central portion of the semiconductor chip 211.

In this example embodiment, each of the conductive patterns 240, which may be electrically connected to each of the pads 230, respectively, may extend to the central portion of the semiconductor chip 211. The land portions 240b may be arranged on the central portion of the semiconductor chip 211 in a matrix configuration, for example.

The insulating photoresist structure 250 may be provided on the surface of the conductive pattern 240. The insulating photoresist structure 250 may have a contact hole 252 for partially exposing a central portion of the land portion 240b of the conductive pattern 240. An outline of the insulating photoresist structure 250 may be substantially similar to that of the conductive pattern 240, except for the contact hole 252. In this example embodiment, the insulating photoresist structure 250 may be fabricated from a photosensitive polyimide film, for example. The insulating photoresist structure 250 may be provided along an upper face of the conductive pattern 240 to insulate the conductive pattern 240 from an external conductive body (not shown).

The conductive bump 260 may have a spherical shape, for example. In alternative embodiments, conductive bumps having numerous and varied shapes may be suitably implemented. The conductive bump 260 may be electrically connected to the conductive pattern 240 exposed through the contact hole 252. The conductive bump 260 may be fabricated from solder (for example) having a melting temperature lower than that of the conductive pattern 240.

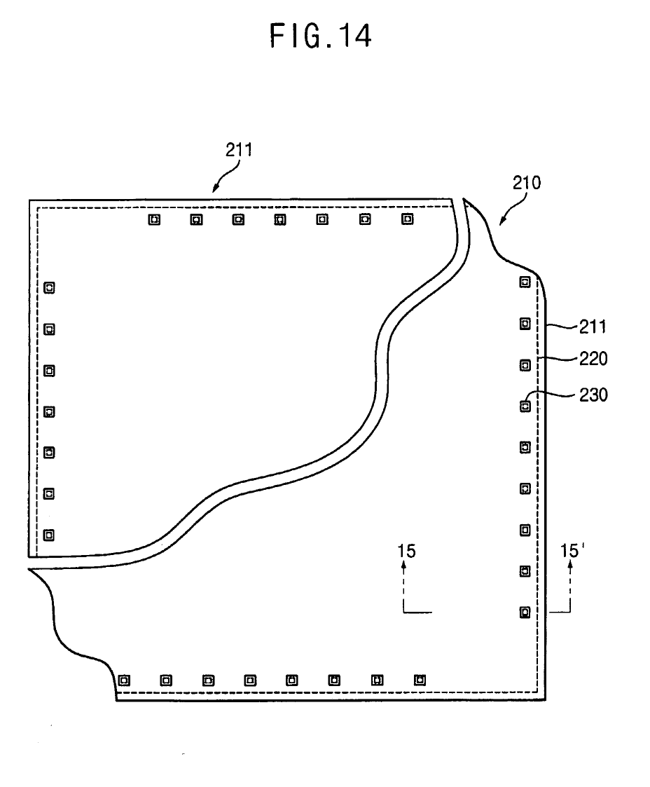

A method that may be implemented to manufacture the wafer level package will be described with reference to FIGS. 14-18.

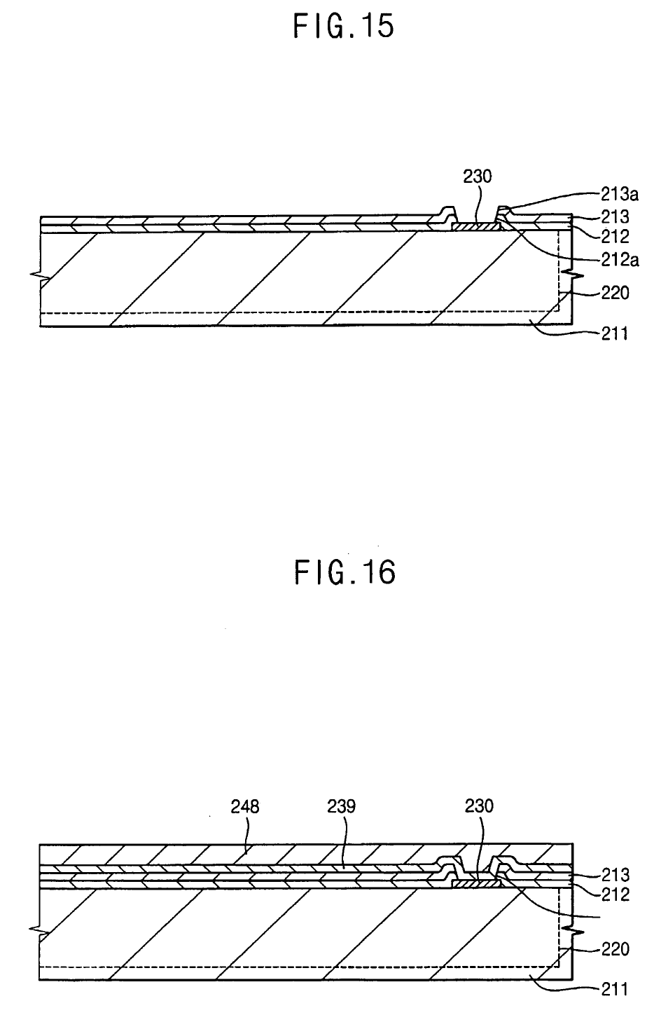

FIG. 14 is a plan view of providing the passivation pattern 212 and the first insulation pattern 213 of the wafer level package, and FIG. 15 is a cross-sectional view taken along the line 15-15 in FIG. 14.

Referring to FIGS. 14 and 15, the semiconductor chip 211 may be provided on the wafer 200 to manufacture the wafer level package. The semiconductor chip 211 may be formed by various processes that are well known in this art.

A circuit unit 220 may be provided in the semiconductor chip 211 by conventional processes. The circuit unit 220 may (for example) process an input signal applied from an exterior to generate a data signal. The pad 230 may be electrically connected to the circuit unit 220 may be provided on the circuit unit 220.

To form the pad 230, a conductive layer (not shown) such as a metal layer (for example) may be provided on the semiconductor chip 211. The conductive layer may be provided by a chemical vapor deposition (CVD) process and/or a sputtering process, for example. The conductive layer may be electrically connected to the circuit unit 220. The conductive layer may be fabricated from an aluminum layer, an aluminum alloy layer, a gold layer, and/or a silver layer, for example. These materials may be used alone or in combination. In this example embodiment, the pad 230 may include an aluminum layer.

A photoresist film (not shown) may be provided on an upper face of the conductive layer. The photoresist film may be provided by a spin coating process, for example. The photoresist film may be patterned by a photo process to provide a photoresist pattern (not shown) on the conductive layer. The conductive layer may be etched using the photoresist pattern as an etching mask, thereby forming the pad 230 on the semiconductor chip 211. The photoresist pattern on the conductive pad 230 may be removed from the pad 230. The photoresist pattern may be removed by an ashing process using O₂ plasma and/or a stripping process, for example.

The pad 230 may (for example) transmit the input signal applied from the exterior to the circuit unit 220 and/or outputs the data signal processed in the circuit unit 220 to the exterior. In this example embodiment, the pad 230 may have a square shape on a plan view. It will be appreciated, however, that pads 230 having numerous and varied shapes may be suitably implemented.

Referring to FIG. 14, the pads 230 may be arranged along an edge of the semiconductor chip 211 in a line. Alternatively, the pads 230 may be arranged along the edge of the semiconductor chip 211 in a plurality of lines. For example, the conductive pads 230 arranged in the lines may be placed in a zigzag shape on a plan view.

Referring to FIG. 15, a passivation layer (not shown) and a first insulation layer (not shown) may be provided on the semiconductor chip 211 to cover the pad 230. The passivation layer and the first insulation layer may be provided by a CVD process and/or a spin coating process, for example.

The passivation layer may be fabricated from an oxide layer and/or a nitride layer, for example. The passivation layer may be provided by a CVD process and/or a high-density plasma (HDP) deposition process, for example.

The first insulation layer may be provided on the passivation layer. The first insulation layer may be provided by a spin coating process, for example. The first insulation layer may be fabricated from a photosensitive polyimide film, for example. The first insulation layer may have a thickness of about 1 μm to about 25 μm, for example.

The first insulation layer may be patterned by a photo process including an exposing process and a developing process to form the first insulation pattern 213. The first insulation layer pattern 213 may have the opening 213a corresponding to a position where the pad 230 is provided. The first insulation pattern 213 may absorb impacts that may be applied from an exterior to protect the body 211 and the circuit unit 220 from damage. Further, the first insulation pattern 213 may insulate the circuit unit 220 from an external conductive body (not shown).

In this example embodiment, the first insulation layer may be exposed by a light beam having exposure energy of about 500 mJ to about 2,500 mJ, for example.

The passivation layer may be etched using the first insulation pattern 213 as an etching mask to form a passivation pattern 212 having the opening 212a for exposing the pad 230.

Alternatively, when the first insulation layer includes an oxide layer and/or a nitride layer (instead of the photosensitive polyimide film), the first insulation layer may be etched using a photoresist pattern as an etching mask to form the first insulation pattern 213 having the opening 213a. For example, a photoresist film may be provided on the first insulation layer, such as the oxide layer and/or the nitride layer, by a spin coating process (for example). The photoresist film may be patterned by a photo process to form a photoresist pattern on the first insulation layer. The photoresist pattern may have an opening corresponding to the conductive pad 230. The first insulation layer and the passivation layer may be etched using the photoresist pattern as an etching mask so that the passivation pattern 212 having the opening 212a and the first insulation pattern 213 having the opening 213a may be provided on the semiconductor chip 211. The photoresist pattern on the pad 230 may be removed by an ashing process and/or a stripping process, for example.

The passivation pattern 212 may absorb impacts that may be applied from the exterior to protect the circuit unit 220 from damage. The first insulation pattern 213 may absorb impacts to protect the circuit unit 220 from damage and may also insulate the circuit unit 220 from an exterior conductive body (not shown).

FIG. 16 is a cross-sectional view of forming a conductive layer 239 and an insulating photoresist film 248 on the first insulation pattern 213.

Referring to FIG. 16, a conductive layer 239 may be provided on an entire surface of the semiconductor chip 211 to cover the first insulation pattern 213. The conductive layer 239 may be provided by a sputtering process and/or a CVD process, for example.

The insulating photoresist film 248 may be provided on the conductive layer 239. The insulating photoresist film 248 may be provided by a spin coating process, for example. The insulating photoresist film 248 may be fabricated from a photosensitive polyimide film, for example.

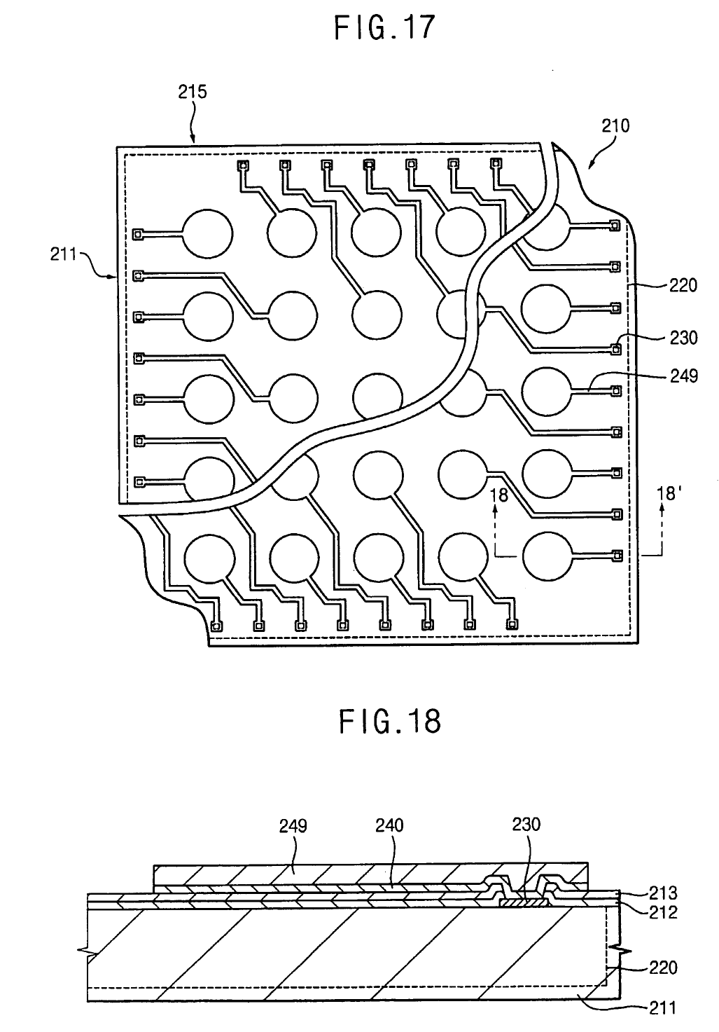

FIG. 17 is a plan view of forming a preliminary photoresist structure 249 and the conductive pattern 240 by patterning the insulating photoresist film 248 and by etching the conductive layer 239 in FIG. 16. FIG. 18 is a cross-sectional view taken from a line 18-18 in FIG. 17.

Referring to FIGS. 17 and 18, a first reticle (not shown) having a light transmitting portion for patterning the insulating photoresist film 248 may be aligned over the insulating photoresist film 248 in substantially the same manner as in FIG. 5. A light beam may pass through the light transmitting portion of the first reticle and be irradiated onto the insulating photoresist film 248 so that the insulating photoresist film 248 is exposed by the light beam. The exposed insulating photoresist film 248 may be developed using a developing solution. Thus, a preliminary photoresist structure 249 may be provided on the conductive layer 239.

The conductive layer 239 may be etched using the preliminary photoresist structure 249 as an etching mask to provide the conductive pattern 240 on the first insulation pattern 213.

One end of the conductive pattern 240 may be electrically connected to the pad 230, which may be electrically coupled to the circuit unit 220. Another end of the conductive pattern 240 may extend to a central portion of the semiconductor chip 211 along an upper face of the first insulation pattern 213. The end of the conductive pattern 240, which may be electrically connected to the pad 230, may also be electrically connected to the land portion of the conductive pattern 240. The land portions may be arranged on the center portion of the semiconductor chip 211 in a matrix configuration, for example.

Referring to FIGS. 12 and 13, a second reticle (not shown), which may have a light transmitting portion corresponding to a portion of the conductive pattern 240, may be arranged over an upper face of the preliminary photoresist structure 249, which may still have a photosensitivity (in substantially the same manner as in FIG. 7). A light beam may pass through the light-transmitting portion and may be irradiated onto the preliminary photoresist structure 249 so that a portion of the preliminary photoresist structure 249 exposed by the light beam may be secondarily exposed.

The secondarily exposed preliminary photoresist structure 249 may be developed by a developing process to form the insulating photoresist structure 250 having the contact hole 252.

In this example embodiment, an outline of the insulating photoresist structure 250 may be substantially similar to that of the conductive pattern 240, except for the contact hole 252.

The insulating photoresist structure 250 may be hardened by a baking process, for example.

The conductive bump 260 may be placed on the conductive pattern 240 exposed through the contact hole 252. The conductive bump 260 on the conductive pattern 240 may be melted in a reflow furnace (for example) for melting a contact portion between the conductive bump 260 and the conductive pattern 240 using infrared rays so that the conductive bump 260 and the conductive pattern 240 may be attached to each other. As a result, the conductive bump 260 and the conductive pattern 240 may be electrically connected to each other, as shown in FIG. 13.

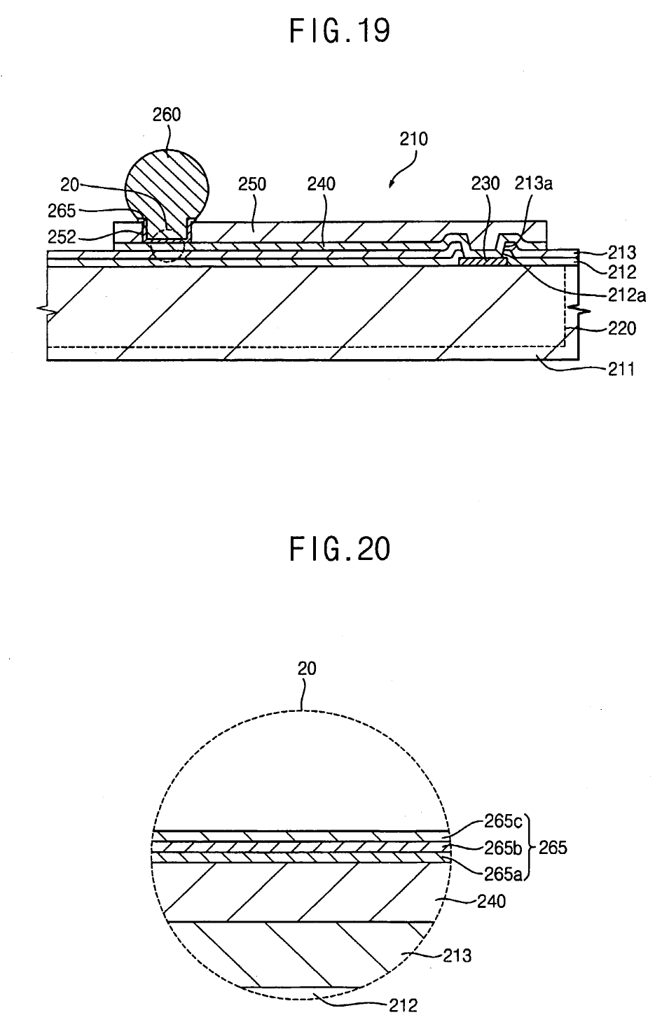

FIG. 19 is a cross-sectional view of an under bump layer of a wafer level package in accordance with another example, non-limiting embodiment of the present invention. FIG. 20 is an enlarged cross-sectional view of the portion 20 in FIG. 19. A wafer level package of the present embodiment may include elements substantially similar to those of the wafer level package in FIGS. 11-13, except for the under bump layer. Thus, the same reference numerals refer to the substantially similar elements in FIGS. 11 to 13 so that any further illustrations of the similar elements are omitted.

Referring to FIGS. 19 and 20, the wafer level package 210 may include an under bump layer 265, which may improve electrical characteristics between the conductive pattern 240 and the conductive bump 260. The under bump layer 265 may be interposed between the conductive pattern 240 and the conductive bump 260 to improve physical adhesion strength and electrical characteristics between the conductive pattern 240 and the conductive bump 260, for example.

The under bump layer 265 may include a conductive adhesion pattern 265a and a conductive wetting pattern 265b. The conductive adhesion pattern 265a may be provided on the conductive pattern 240. The conductive wetting pattern 265b may be provided on the conductive adhesion pattern 265a. The under bump layer 265 may include an oxidation-inhibiting pattern 265c for inhibiting an oxidation of the under bump layer 265 and the conductive pattern 240.

In this example embodiment, the conductive adhesion pattern 265a may be fabricated from chromium (Cr), nickel (Ni) and/or tungsten-titanium (TiW), for example. The conductive wetting pattern 265b may be fabricated from copper (Cu), nickel (Ni) and/or nickel-vanadium (NiV), for example.

In this example embodiment, although the under bump layer 265 may include the conductive adhesion pattern 265a, the conductive wetting pattern 265b and the oxidation-inhibiting pattern 265c in FIG. 20, the under bump layer 265 may include at least one among the conductive adhesion pattern 265a, the conductive wetting pattern 265b and the oxidation-inhibiting pattern 265c.

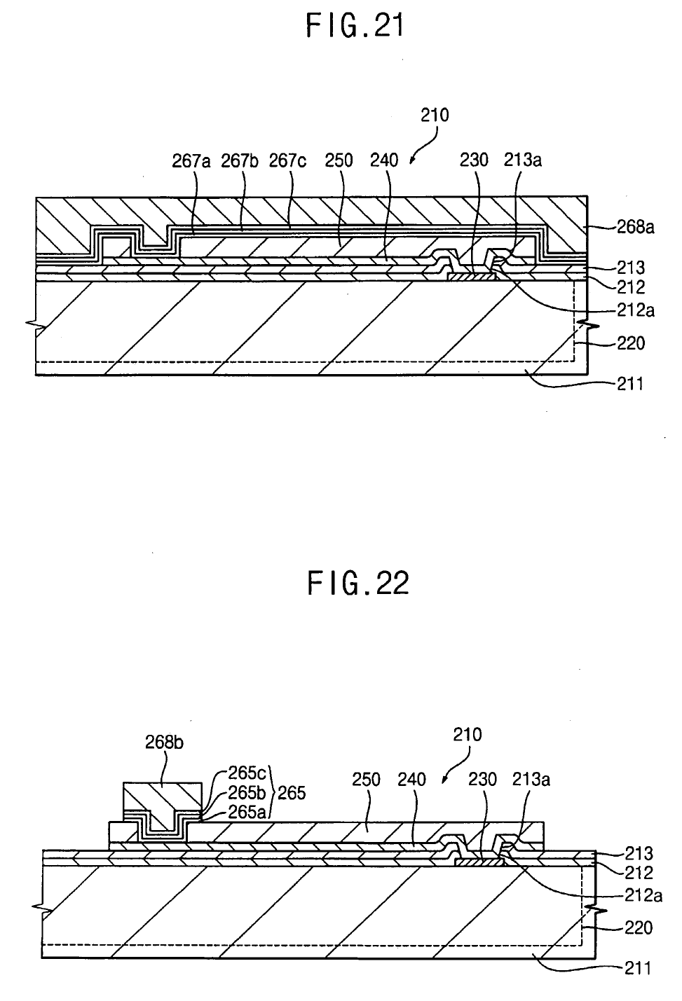

A method that may be implemented to manufacture the under bump layer 265 will be described with reference to FIGS. 21 and 22.

FIG. 21 is a cross-sectional view of providing a conductive adhesion layer 267a, a conductive wetting layer 267b and an oxidation inhibition layer 267c.

Referring to FIG. 21, to provide the under bump layer 265, a conductive adhesion layer 267a, a conductive wetting layer 267b and an oxidation-inhibiting layer 267c may be provided on the semiconductor chip 211. In this example embodiment, the conductive adhesion layer 267a, the conductive wetting layer 267b and the oxidation-inhibiting layer 267c may be provided by a sputtering process and/or a CVD process, for example.

A photoresist film 268a may be provided on the oxidation-inhibiting layer 267c. The photoresist film 268a may be provided by a spin coating process, for example.

FIG. 22 is a cross-sectional view of providing the under bump layer 265 by etching the conductive adhesion layer 267a, the conductive wetting layer 267b and the oxidation inhibition layer 267c in FIG. 21.

Referring to FIG. 22, the photoresist film 268a provided on the oxidation-inhibiting layer 267c may be patterned by a photo process including an exposing process and a developing process to provide a photoresist pattern 268b on the oxidation-inhibiting layer 267c. The photoresist pattern 268b may be selectively provided on a portion where the contact hole 252 of the insulating photoresist structure 250 is formed.

The conductive adhesion layer 267a, the conductive wetting layer 267b and the oxidation-inhibiting layer 267c may be etched using the photoresist pattern 268b as an etching mask to provide the under bump layer 265 including the conductive adhesion pattern 265a, the conductive wetting pattern 265b, and the oxidation-inhibiting layer 265c on the conductive pattern 240. In this example embodiment, a portion of the under bump layer 265 may be placed on the insulating photoresist structure 250. The photoresist pattern 268b may be removed by an ashing process and/or a stripping process, for example. The conductive bump 260 may be attached on the under bump layer 265 in substantially the same manner as in FIG. 13

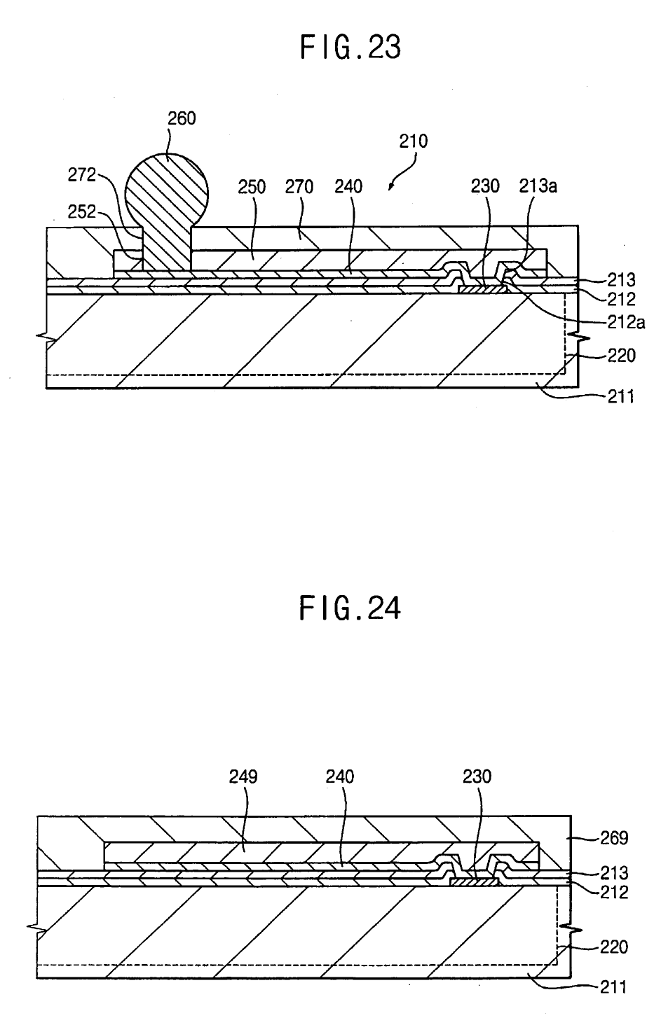

FIG. 23 is a cross-sectional view of a wafer level package in accordance with another example, non-limiting embodiment of the present invention. A wafer level package of this example embodiment may include elements substantially similar to those of the wafer level package according to the previous embodiment, except for a second insulation pattern 270. Thus, same reference numerals refer to the substantially similar elements in FIG. 13-18 so that any further illustrations of the similar elements are omitted.

Referring to FIG. 23, the second insulation pattern 270 may be provided on the first insulation pattern 213. The second insulation pattern 270 may be provided on the first insulation pattern 213 to cover the insulating photoresist structure 250. In this example embodiment, the second insulation pattern 270 may have a thickness of about 1 μm to about 30 μm, for example. The second insulation pattern 270 may be fabricated from a photosensitive polyimide film, for example.

The second insulation pattern 270 may have an opening 272 corresponding to a position where the contact hole 252 of the insulating photoresist structure 250 is formed. Thus, the conductive pattern 240 may be partially exposed through the opening 272. For example, the second insulation pattern 270 may cover exposed sidewalls of the conductive pattern 240 to insulate the exposed sidewalls from an external conductive body (not shown). Further, the second insulation pattern 270 may absorb impacts that may be applied from an exterior to protect the conductive pattern 240 and the circuit unit 220 from damage.

A method that may be implemented to manufacture the wafer level package in accordance with this example embodiment will be described with reference to FIGS. 24-26. A method of manufacturing the wafer level package may include processes substantially similar to those in the method of manufacturing the wafer level package depicted in FIGS. 14-18, except for providing the second insulation pattern 270. Thus, the same reference numerals refer to substantially similar elements in FIGS. 14-18 so that any further illustrations of the similar elements are omitted.

FIG. 24 is a cross-sectional of providing a second insulation layer 269

Processes may be carried out in substantially the same manner as in FIGS. 17 and 18 to form the preliminary photoresist structure 249 and the conductive pattern 240 on the semiconductor chip 211 in FIG. 24.

Referring to FIG. 24, the second insulation layer 269 may be provided on an entire surface of the semiconductor chip 211 to cover the preliminary photoresist structure 249. The second insulation layer 269 may be provided by a spin coating process, for example. The second insulation layer 269 may be fabricated from a photosensitive polyimide film, for example. In this example embodiment, the second insulation layer 269 may have a photosensitive substance substantially the same as that of the preliminary photoresist structure 249.

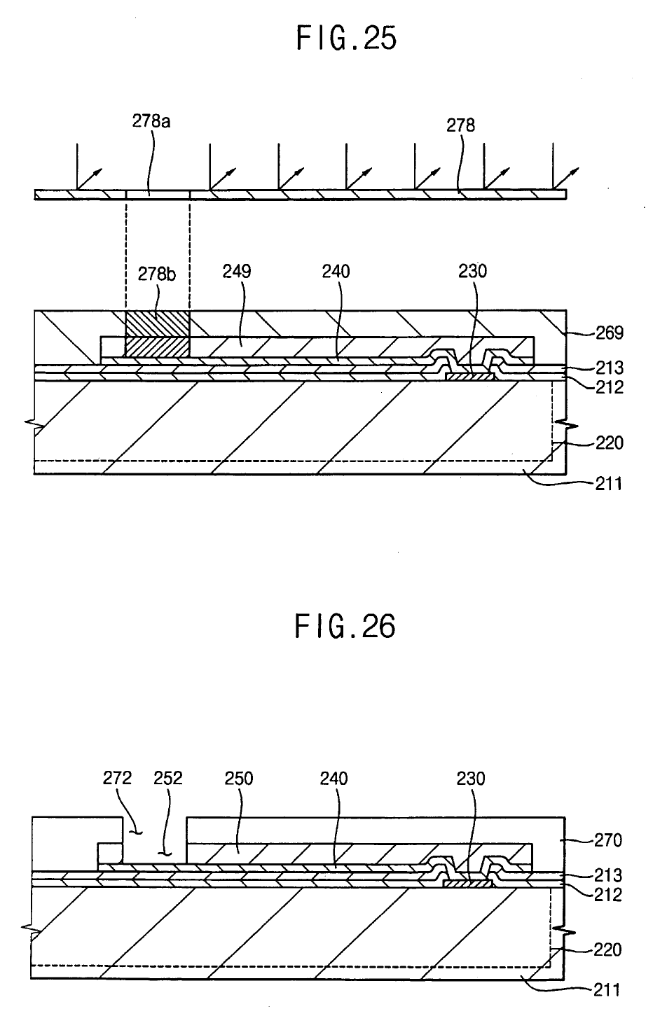

FIG. 25 is a cross-sectional view of exposing the second insulation layer 269 and the preliminary photoresist structure 249.

Referring to FIG. 25, a third reticle 278 may have a light transmitting portion 278a. The third reticle 278 may be placed over the second insulation layer 269. In this example embodiment, the light transmitting portion 278a may be partially overlapped with the conductive pattern 240 so that the light-transmitting portion 278a may be placed over a position where a contact hole for partially exposing the conductive pattern 240 is to be formed. The third reticle 278 may be substantially similar to the reticle in FIG. 10.

A light beam may pass through the light-transmitting portion 278a and be irradiated onto the second insulation layer 269 to expose the second insulation layer 269 and the preliminary photoresist structure 249. Thus, the second insulation layer 269 and the preliminary photoresist structure 249 may be optically reacted with the light beam so that a solubility of exposed regions 278b of the second insulation layer 269 and the preliminary photoresist structure 249 exposed by the light beam may be higher than that of a non-exposed region of the second insulation layer 269 and the preliminary photoresist structure 249 that may be located around the exposed region 278b. In this example embodiment, an exposure energy for exposing the second insulation layer 269 and the preliminary photoresist structure 249 may be about 500 mJ to about 3,000 mJ, for example.

FIG. 26 is a cross-sectional view of providing the second insulation pattern 270 and the insulating photoresist structure 250.

When the second insulation layer 269 and the preliminary photoresist structure 249 that may be exposed through the light beam are developed by a developing process, the exposed region 278b including a photosensitive substance may be removed by the developing process to form the insulating photoresist structure 250. Here, the insulating photoresist structure 250 may have the contact hole 252 and the second insulation pattern 270 may have the contact hole 272. Thus, the conductive pattern 240 may be partially exposed through the contact holes 252 and 272.

In this example embodiment, the insulating photoresist structure 250 and the second insulation pattern 270 may include a positive photosensitive insulating photoresist substance. Alternatively, the insulating photoresist structure 250 and the second insulation pattern 270 may include a negative photosensitive insulating photoresist substance.

Referring to FIG. 23, the conductive bump 260 may be placed on the conductive pattern 240 that may be exposed through the contact holes 252 and 272. The conductive bump 260 may be melted by an attaching process so that the contact holes 252 and 272 may be filled with the melted conductive bump 260. As a result, the conductive bump 260 may be electrically connected to the conductive pattern 240.

According to example, non-limiting embodiments of the present invention, the preliminary photoresist structure may be provided on the conductive pattern. The contact hole for exposing the conductive pattern may be provided through the preliminary photoresist structure without removing the preliminary photoresist structure for forming the conductive pattern that may be electrically connected to the conductive pad. That is, the photoresist film on the metal layer may be patterned by two photo processes to form the insulating photoresist structure. Thus, the wiring structure may be formed by convenient manufacturing processes.

The foregoing is illustrative of example, non-limiting embodiments of the present invention and is not to be construed as limiting thereof. Although example embodiments of the invention have been described, those skilled in the art will readily appreciate that numerous and varied modifications may be suitably implemented without departing from the novel teachings and advantages of this invention. Accordingly, all such modifications are intended to be included within the spirit and scope of this invention as defined in the claims.

What is claimed is:

1. A wiring structure comprising:
a body having a circuit unit;
a pad provided on the body and electrically connected to the circuit unit;
a conductive pattern provided on the body and electrically connected to the pad; and
an insulating photoresist structure provided on a surface of the conductive pattern, the insulating photoresist structure having a contact hole through which the conductive pattern is partially exposed.

2. The wiring structure of claim 1, wherein the conductive pattern comprises at least one material selected from the group consisting of Ti/Cu, TiW/Ni, TiW/NiV, Cr/Cu, Cr/Ni, Cr/NiV, Ti/Cu/Ni, TiW/Cu/Ni, TiW/Cu/NiV and Cr/Cu/NiV.

3. The wiring structure of claim 1, wherein the conductive pattern has a thickness of about 1,000 Å to about 7,000 Å.

4. The wiring structure of claim 1, wherein an outline of the insulating photoresist structure is substantially the same as that of the conductive pattern.

5. The wiring structure of claim 1, further comprising a passivation pattern interposed between the body and the conductive pattern, the passivation pattern having a first opening through which the pad is partially exposed.

6. The wiring structure of claim 5, further comprising a first insulation pattern interposed between the passivation pattern and the conductive pattern, the first insulation pattern having a second opening corresponding to the first opening.

7. The wiring structure of claim 6, wherein a thickness of the first insulation pattern is about 1 μm to about 25 μm.

8. The wiring structure of claim 6, further comprising a second insulation pattern provided on an upper face of the insulating photoresist structure and exposed sidewalls of the first insulation pattern, the second insulation pattern having a third opening corresponding to the contact hole.

9. The wiring structure of claim 8, wherein a thickness of the second insulation pattern is about 1 μm to about 25 μm.

10. A method of manufacturing a wiring structure, the method comprising:
providing a first insulation pattern on a body that includes a circuit unit and a pad electrically connected to the circuit unit, the pad being exposed through the first insulation pattern;
providing a conductive layer on the first insulation pattern, the conductive layer being electrically coupled to the pad;
providing an insulating photoresist film on the conductive layer;
exposing and developing the insulating photoresist film to provide a preliminary photoresist structure on the conductive layer;
etching the conductive layer using the preliminary photoresist structure as an etching mask to provide a conductive pattern on the body; and
exposing and developing the preliminary photoresist structure to provide an insulating photoresist structure having a contact hole through which the conductive pattern is exposed.

11. The method of claim 10, further comprising:
before providing the first insulation pattern, providing a passivation pattern on the body, the passivation pattern having a first opening through which the pad is exposed.

12. The method of claim 11, wherein the first insulation pattern has a second opening corresponding to the first opening.

13. The method of claim 11, wherein providing the first insulation pattern comprises:
providing a first insulation layer having photosensitivity on an upper face of the passivation pattern;
exposing a portion of the first insulation layer corresponding to the first opening; and
developing the first insulation layer to remove an exposed portion of the first insulation layer;
wherein an exposure energy for exposing the first insulation layer is about 500 mJ to about 2,500 mJ.

14. The method of claim 10, further comprising providing a second insulation pattern on the insulating photoresist structure, the second insulation pattern having a third opening corresponding to the contact hole.

15. The method of claim 14, wherein providing the second insulation pattern comprises:
providing a second insulation layer having a photosensitivity on the body to cover the insulating photoresist structure;
exposing a portion of the second insulation layer corresponding to the contact hole; and
developing the second insulation layer to remove the exposed portion of the second insulation layer;
wherein an exposure energy for exposing the second insulation layer is about 500 mJ to about 2,500 mJ.

16. The method of claim 10, further comprising baking the insulating photoresist structure.

17. A wafer level package comprising:
the wiring structure of claim 1, wherein the body is a semiconductor chip; and
a conductive member filling the contact hole and electrically connected to the conductive pattern.

18. The wafer level package of claim 17, further comprising a passivation pattern interposed between the semiconductor chip and the conductive pattern, the passivation pattern having a first opening through which the pad is partially exposed.

19. The wafer level package of claim 18, further comprising a first insulation pattern interposed between the passivation pattern and the conductive pattern, the first insulation pattern having a second opening corresponding to the first opening.

20. The wafer level package of claim 19, further comprising a second insulation pattern provided on an upper face of the insulating photoresist structure and exposed faces of the first insulation pattern, the second insulation pattern having a third opening corresponding to the contact hole.

21. The wafer level package of claim 17, further comprising an under bump layer interposed between the conductive pattern and the conductive member to electrically connect the conductive pattern to the conductive member.

22. The wafer level package of claim 21, wherein the under bump layer comprises a conductive adhesion pattern attached to the conductive pattern, and a conductive wetting pattern provided on the conductive adhesion pattern.

23. The wafer level package of claim 22, wherein the under bump layer further comprises an oxidation-inhibiting pattern provided on the conductive wetting pattern.

24. The wafer level package of claim 17, wherein the conductive member is a solder ball having a spherical shape.

25. A method of manufacturing a wafer level package, comprising:
performing the method of claim 12, wherein the body is a semiconductor chip in a wafer; and
filling the contact hole with a conductive member electrically connected to the conductive pattern.

26. The method of claim 25, further comprising:
before providing the conductive member, providing an under bump layer on the conductive pattern.

27. The method of claim 25, further comprising providing a second insulation pattern on the insulating photoresist structure, the second insulation pattern having a third opening corresponding to the contact hole.

28. The method of claim 25, further comprising baking the insulating photoresist structure.
